(19) United States
(12) Patent Application Publication
(10) Pub. No.: US 2025/0194139 A1
(43) Pub. Date: Jun. 12, 2025

(54) SEMICONDUCTOR DEVICE

(71) Applicant: Vanguard International Semiconductor Corporation, Hsinchu (TW)

(72) Inventors: Chen-Dong TZOU, Taipei City (TW); Yun-Kai LAI, Taichung City (TW); Chia-Hao LEE, Zhubei City (TW)

(73) Assignee: Vanguard International Semiconductor Corporation, Hsinchu (TW)

(21) Appl. No.: 18/535,659

(22) Filed: Dec. 11, 2023

(51) Int. Cl. H01L 29/78; H01L 29/06

(52) U.S. Cl. CPC H10D 30/601; H10D 62/124

(57) ABSTRACT

A semiconductor device is provided. The semiconductor device includes a substrate, an epitaxial layer, a pair of well regions, a pair of doping regions, a pair of first conductive structures, and a second conductive structure. The epitaxial layer is disposed on the substrate. The well regions are disposed in the epitaxial layer. The doping regions are disposed in the well regions. Each first conductive structure is disposed on the side of the respective well region. The second conductive structure is disposed on the well regions.

### BACKGROUND OF THE INVENTION

### Field of the Invention

The present disclosure relates to a semiconductor device, and in particular to a Double Diffused Metal Oxide Semiconductor field-effect transistor (DMOSFET) that combines a planar gate and a trench gate.

### Description of the Related Art

High-voltage component technology is generally used in high-voltage and high-power circuits or drive circuits. Double-diffused metal oxide semiconductor field-effect transistors with planar gates and trench gates and the like have been developed currently.

However, existing structures are still unsatisfactory. For example, whether the double-diffused metal-oxygen semi-field effect transistor is a planar gate or a trench gate, the current density in its channel region is still insufficient, and performance does not meet expectations. Therefore, the industry still needs to improve methods of reducing on-resistance (Ron) and improve performance.

### BRIEF SUMMARY OF THE INVENTION

Some embodiments of the present disclosure provide a semiconductor structure. The semiconductor device includes a substrate, an epitaxial layer, a pair of well regions, a pair of doping regions, a pair of first conductive structures, and a second conductive structure. The epitaxial layer is disposed on the substrate. The well regions are disposed in the epitaxial layer. Each of the doping regions is disposed in one of the well regions. The two first conductive structures are disposed on respective sides of the well regions. The second conductive structure is disposed on the well regions. The epitaxial layer and the doping regions have a first conductivity type. The well regions have a second conductivity type. The second conductivity type is different from the first conductivity type.

Some embodiments of the present disclosure also provide a semiconductor device. The semiconductor structure includes a substrate, an epitaxial layer, and at least one structural unit. The epitaxial layer is disposed on the substrate. Each of the structural units includes: a pair of first conductive structures, a second conductive structure, a pair of well regions, and a pair of doping regions. The pair of first conductive structures is disposed on the outermost side of the structural unit. The second conductive structure is disposed on the epitaxial layer. The pair of well regions is disposed between the pair of first conductive structures. The pair of doping regions is disposed in the pair of well regions. The epitaxial layer and the doping regions have a first conductivity type. The well regions have a second conductivity type. Each structural unit is symmetrical to the center of the second conductive structure.

Some embodiments of the present disclosure also provide a semiconductor device. The semiconductor structure includes a substrate, an epitaxial layer, and at least one structural unit. The epitaxial layer is disposed on the substrate. Each structural unit includes: a well region, a doping region, a first conductive structure, and a second conductive structure. The well region is disposed in the epitaxial layer. The doping region is disposed in the well region. The first conductive structure is disposed in the epitaxial layer. The second conductive structure is disposed on the epitaxial layer. The epitaxial layer and the doping region have a first conductivity type. The well region has a second conductivity type that is different from the first conductivity type. The well region and the first conductive structure are respectively disposed under both sides of the second conductive structure

### BRIEF DESCRIPTION OF THE DRAWINGS

The present disclosure can be more fully understood by reading the subsequent detailed description and examples with references made to the accompanying drawings, wherein:

FIG. 1 is a cross-sectional view of a semiconductor device according to a first embodiment of some embodiments of the present disclosure.

FIG. 1-1 is a top view of a semiconductor device according to the first embodiment of some embodiments of the present disclosure.

FIG. 1-2 is another cross-sectional view of a semiconductor device according to a first embodiment of some embodiments of the present disclosure.

FIG. 2 is a cross-sectional view of a semiconductor device according to a second embodiment of some embodiments of the present disclosure.

FIG. 3 is a cross-sectional view of a semiconductor device according to a third embodiment of some embodiments of the present disclosure.

FIG. 3-1 is a top view of some components in a semiconductor device according to a third embodiment of some embodiments of the present disclosure.

FIG. 3-2 is a top view of some components in a semiconductor device according to a third embodiment of some embodiments of the present disclosure.

FIG. 4 is a cross-sectional view of a semiconductor device according to a fourth embodiment of some embodiments of the present disclosure.

FIG. 5 is a cross-sectional view of a semiconductor device according to a fifth embodiment of some embodiments of the present disclosure.

FIG. 6 is a cross-sectional view of a semiconductor device according to a sixth embodiment of some embodiments of the present disclosure.

### DETAILED DESCRIPTION OF THE INVENTION

The following disclosure provides many different embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described below. In the different drawings and described embodiments, similar reference numerals are used to designate similar elements. It will be appreciated that additional operations may be provided before, during, and after the method, and that some of the described operations may be replaced or deleted for other embodiments of the foregoing method.

Furthermore, spatially relative terms, such as “over”, “below,” “lower,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented and the spatially relative descriptors used herein may likewise be interpreted accordingly.

Embodiments of the present disclosure have a double diffused metal oxide semiconductor field effect transistor (DMOS) (hereinafter referred to as a conductive structure) that combines a planar gate and a trench gate, thereby reducing on-voltage while maintaining the breakdown voltage. In addition, by providing a shielding layer covering the edge of the bottom of the conductive structure, embodiments of the present disclosure may further reduce the electric field of the conductive structure and reduce the parasitic capacitance between the gate and the drain. In addition, in embodiments of the present disclosure, the shielding layer covers the edge of the bottom of the conductive structure, which may further reduce the electric field of the conductive structure at the corners. In addition, embodiments of the present disclosure may further reduce the gate-to-drain capacitance by using a conductive structure with a separated gate, thereby improving the switching characteristics of the semiconductor device. In addition, embodiments of the present disclosure further use an asymmetric semiconductor device to form an electron accumulation layer on one side of the conductive structure to further reduce the on-resistance. Based on the above, the embodiment of the present disclosure may increase the switching speed and reduce the energy loss, thereby improving the performance of the semiconductor device.

Some variations of the embodiments are described below. In the various drawings and illustrated embodiments, similar reference numerals are used to identify similar elements. In addition, in the diagram description below, when the same or similar components are distributed in different areas, the component symbol located on the left side of the drawing (or −X direction side) contains “A”, and the component symbol located on the right side of the drawing (or X direction side), the component symbol contains “B”. It should be noted that additional components may be added to the semiconductor devices in the embodiments described below. Moreover, in different embodiments, some components described below may also be moved, deleted, or replaced.

### First Embodiment

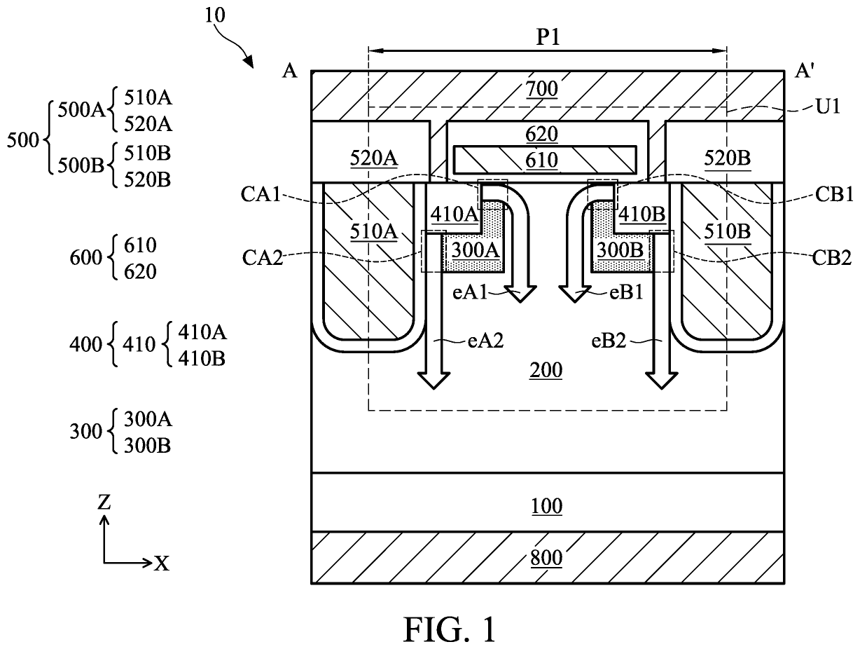

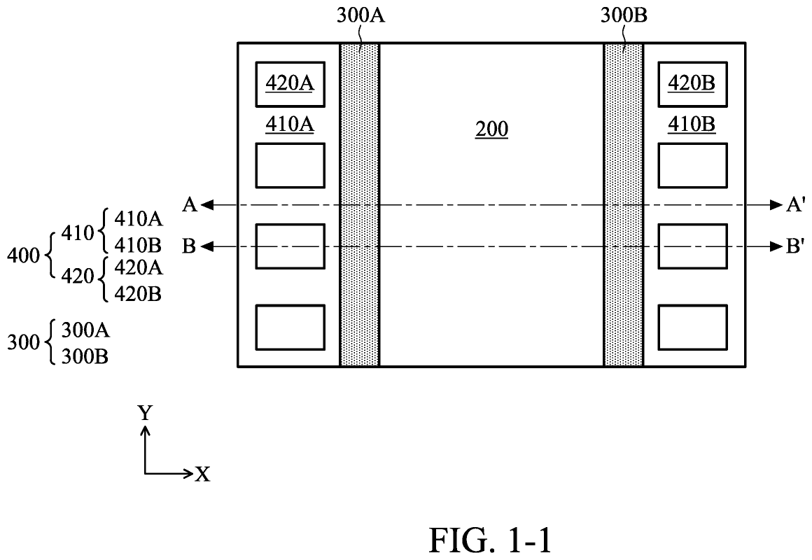

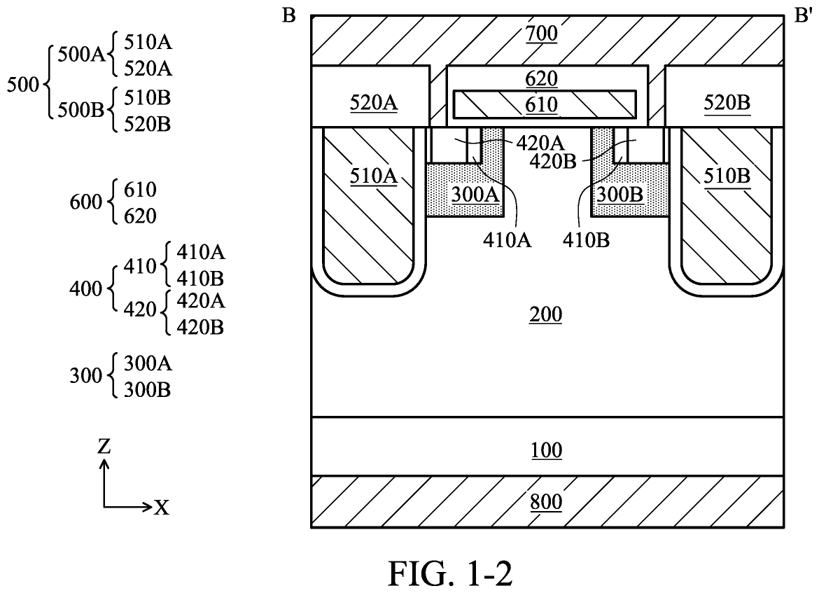

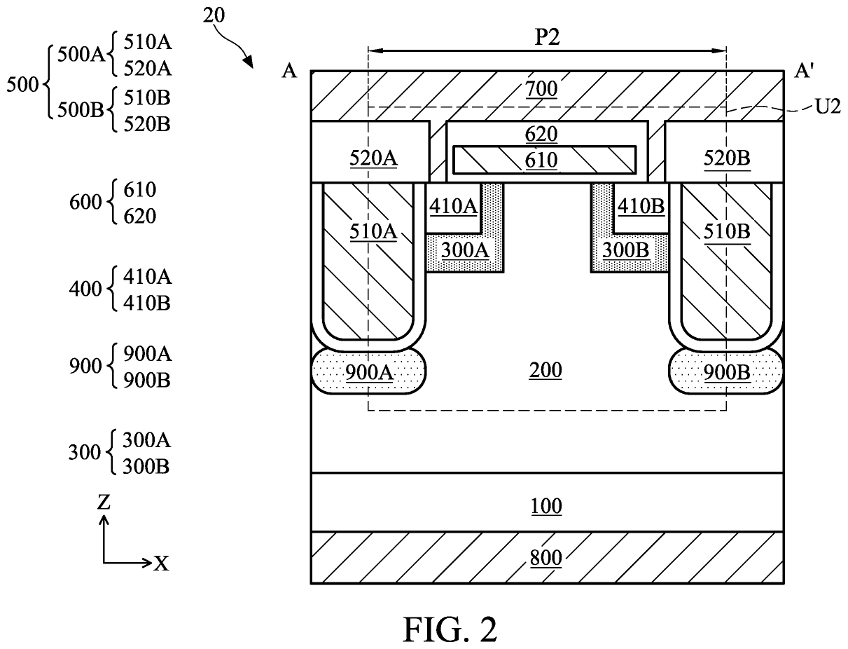

According to a first embodiment of some embodiments of the present disclosure, FIG. 1, FIG. 1-1 and FIG. 1-2 respectively show a cross-sectional view and a top view along the section line AA′ and a cross-sectional view along the section line BB′ of the semiconductor device 10.

First, please referring to FIG. 1, in the embodiment of FIG. 1, the semiconductor device 10 includes a substrate 100 and an epitaxial layer 200 disposed on the substrate 100. In one example, the semiconductor device 10 further includes a well region 300 disposed in the epitaxial layer 200 and a doping region 400 disposed in the well region 300. The well region 300 may include a pair of well regions 300A and 300B. The doping region 400 may include a pair of first doping regions 410A and 410B. In some embodiments, the semiconductor device 10 further includes a first conductive structure 500 disposed on one side of the well region 300. Specifically, the first conductive structure 500 may include a pair of conductive structures 500A and 500B, which are respectively disposed on one side of the well region 300A and one side of the well region 300B. More specifically, the pair of conductive structures 500A and 500B are disposed outside the pair of well regions 300A and 300B. In some embodiments, the semiconductor device 10 further includes a second conductive structure 600 disposed on the well region 300.

In addition, in another example, the semiconductor device 10 further includes at least one structural unit U1. This structural unit includes: a pair of first conductive structures 500A and 500B disposed on the outermost side of the structural unit U1, and a second conductive structure 600 disposed on the epitaxial layer 200. This structural unit further includes: a pair of well regions 300A and 300B disposed between the first conductive structures 500A and 500B, and a pair of first doping regions 410A and 410B is disposed in the well regions 300A and 300B. The structural unit U1 is symmetrical to the center of the second conductive structure 600.

In some embodiments, the structural unit U1 has a pitch P1, which is defined as the distance between the center of the first conductive structure 500A and the center of the first conductive structure 500B. The structural unit U1 may be regarded as the smallest functional unit of the semiconductor device 10. For example, it may be regarded as a set of dual gate field effect transistors. That is, the semiconductor device 10 may have a plurality of structural units U1.

Each element in the semiconductor device 10 will be described in detail below.

In some embodiments, the substrate 100 may be made of silicon or other semiconductor materials, such as silicon wafer, bulk semiconductor or wide bandgap semiconductor. In some embodiments, the substrate 100 may be an elemental semiconductor, such as a silicon substrate; the substrate 100 may also be a compound semiconductor, such as a silicon carbide substrate or a gallium nitride substrate. In some embodiments, the substrate 100 may be a doped or undoped semiconductor substrate. In the case where the substrate 100 is doped, the substrate 100 may be p-type.

In some embodiments, the epitaxial layer 200 has a first conductivity type, such as n-type. In some embodiments, the doping concentration of the epitaxial layer 200 may be approximately 10¹⁵-10¹⁷ atoms/cm³. In some embodiments, the formation of the epitaxial layer 200 may include: performing an epitaxial growth process on the substrate 100 or performing an implantation process on the substrate 100, such as metal organic chemical vapor deposition (MOCVD), plasma-enhanced chemical vapor deposition (PECVD), molecular beam epitaxy (MBE), hydride vapor phase epitaxy (HVPE), liquid phase epitaxy (LPE), chloride vapor phase epitaxy (CI-VPE), another suitable process method, or a combination thereof. In embodiments of the present disclosure, the epitaxial layer 200 having the first conductivity type may serve as a drift region of the semiconductor device.

In some embodiments, the well region 300 (including the well region 300A and the well region 300B) is disposed in an upper region of the epitaxial layer 200. In the embodiment of FIG. 1, in the first direction X, the well region 300A and the well region 300B are separated from each other by the epitaxial layer 200. In the embodiment of FIG. 1, the well region 300 may serve as a channel region of the semiconductor device.

In some embodiments, the well region 300 (which includes well region 300A and well region 300B) has a second conductivity type (which is different than the first conductivity type), such as p-type, and its dopant is, for example, aluminum (Al), boron (B) or another suitable dopant. In some embodiments, the doping concentration of the well region 300 may be greater than the doping concentration of the epitaxial layer 200. For example, the doping concentration of the well region 300 may be approximately 10¹⁷-5×10¹⁸ atoms/cm³. In some embodiments, the formation of the well region 300 may include an ion implantation process or the like.

In some embodiments, the doping region 400 includes a first doping region 410 (including a first doping region 410A and a first doping region 410B). In other embodiments, the doping region 400 may further include a second doping region (please referring to the following as shown in FIG. 1-2). In the embodiment of FIG. 1 the first doping region 410A and the first doping region 410B are respectively disposed in the well region 300A and the well region 300B. That is, the first doping region 410A and the first doping region 410B are separated from each other by the well region 300A, the epitaxial layer 200 and the well region 300B. Thereby, the well regions 300A and 300B may be subsequently connected to the source through good ohmic contact in order to reduce the influence of the body effect and stabilize the starting voltage. In the embodiment of FIG. 1, the depth of the first doping region 410A or the first doping region 410B does not exceed the depth of the well region 300A or the well region 300B (for example, the well region 300A covers the bottom surface of the first doping region 410A) to reduce the influence of body effect.

In some embodiments, the first doping region 410 has a first conductivity type, such as n-type. In some embodiments, the doping concentration of the first doping region 410 may be approximately 10¹⁹-5×10²⁰ atoms/cm³ to facilitate the subsequent formation of an ohmic contact interface with the metal thereon.

In some embodiments, an implantation process may be performed on the top surface of the epitaxial layer 200 to obtain the first doping region 410.

In some embodiments, the first conductive structure 500 (including the first conductive structure 500A and the first conductive structure 500B) is disposed on one side of the well region 300. In the embodiment of FIG. 1, the first conductive structure 500A and the first conductive structure 500B are disposed outside the well regions 300A and 300B. Alternatively, in the first direction X, the first conductive structures 500A and 500B are separated from each other by the well region 300A, the epitaxial layer 200 and the well region 300B. In more detail, the first conductive structure 500A is disposed on the left side (the side of −X direction) of the well region 300A, and the first conductive structure 500B is disposed on the right side (the side of +X direction) of the well region 300B.

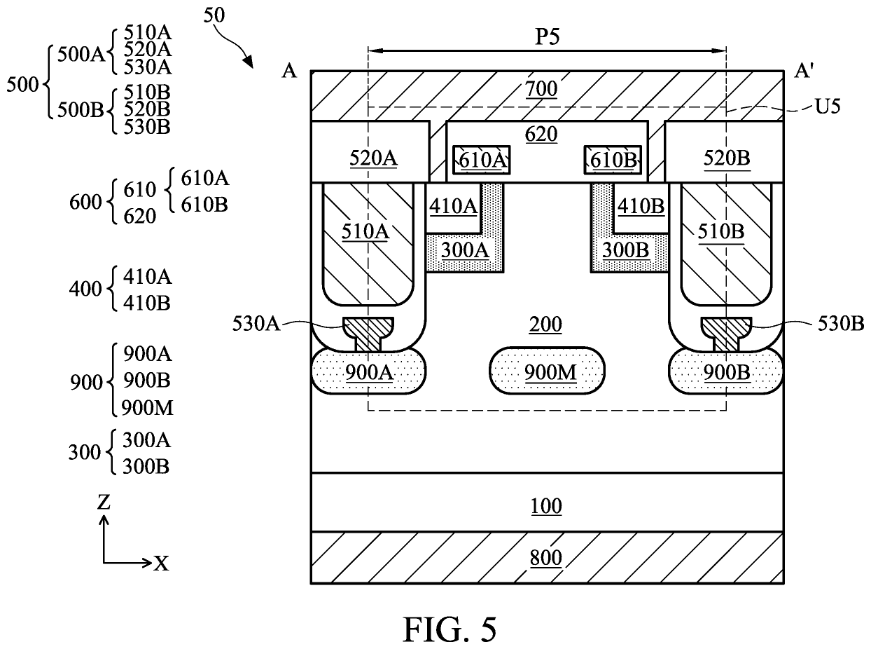

The first electrode structure 500 (including the first conductive structures 500A and 500B) may be a general trench gate structure (as shown in FIG. 1) or a split gate trench (as shown in FIG. 5) structure. In the embodiment of FIG. 1, the first conductive structure 500A and the first conductive structure 500B are general trench gate structures, which respectively include a first conductive layer 510A and a first dielectric layer 520A surrounding the first conductive layer 510A, and first conductive layer 510B and first dielectric layer 520B surrounding first conductive layer 510B. In the embodiment of FIG. 1, the first conductive layer 510A and the first conductive layer 510B themselves may also be regarded as gates of the semiconductor device 10.

In some embodiments, the first conductive layer 510A or 510B may be a single-layer or multi-layer structure of conductive material, which is made of amorphous silicon, polycrystalline silicon, one or more metals, metal nitrides, metal silicides, conductive metal oxide, or a combination of the aforementioned materials. In some embodiments, the metal may include, but is not limited to, tungsten (W), titanium (Ti), tantalum (Ta), and platinum (Pt). In some embodiments, metal nitrides may include, but are not limited to, titanium nitride (TiN) and tantalum nitride (TaN). In some embodiments, the metal silicide may include, but is not limited to, tungsten silicide (WSiₓ). In some embodiments, the first conductive layer 510A or 510B may selectively include dopants with the second conductivity type, that is, p-type, which may be aluminum (Al), boron (B), boron difluoride (BF₂), or another suitable dopant.

In some embodiments, the formation of the first conductive layer 510A or 510B may include a deposition process, a thermal process (such as an annealing process), a removal process, other suitable processes, and the like. In some embodiments, the deposition process may include metal organic chemical vapor deposition (MOCVD), sputtering, resistance heating evaporation, electron beam evaporation, suitable methods, and the like. In some embodiments, the removal process may include a planarization process, etching process, and the like, such as chemical mechanical polishing (CMP) process, dry etching process, and the like.

In some embodiments, the first dielectric layer 520A or 520B may be silicon oxide, other suitable dielectric materials, or a combination of the foregoing materials. In some embodiments, the formation of the first dielectric layer 520A or 520B may include a conformally deposition process or an oxidation process, other suitable processes, and the like. In some embodiments, the oxidation process may be thermal oxidation or another suitable process. In some embodiments, the deposition process may be a physical vapor deposition (PVD) process, a chemical vapor deposition (CVD) process, a plasma enhance chemical vapor deposition (PECVD) process, other suitable processes, or a combination of the aforementioned processes.

For example, the formation of the first conductive structure 500A (or 500B) may include the following steps: forming a trench at a predetermined position through an etching process; forming a first dielectric layer 520A (or 520B) in the trench through an oxidation process; forming a conductive material thereon through a deposition process; and removing an excess conductive material through a removal process to form the first conductive layer 510A (or 510B).

The aforementioned photolithography process may include photoresist coating (for example, spin coating), soft baking, mask alignment, exposure, post-exposure baking, photoresist development, cleaning and drying (for example, hard baking), other suitable processes or combinations of the above. The aforementioned etching process may include a dry etching process, a wet etching process, or another suitable etching process. The aforementioned dry etching may include plasma etching, plasma-free gas etching, sputter etching, ion milling, reactive ion etching (RIE), and neutral beam etching (NBE), inductive coupled plasma etching. The aforementioned wet etching may include using an acidic solution, an alkaline solution or a solvent to remove at least a portion of the structure to be removed. In addition, the etching process may also be pure chemical etching, pure physical etching, or any combination thereof.

In some embodiments, the second conductive structure 600 is disposed on the well region 300. In the embodiment of FIG. 1, the second conductive structure 600 spans over the well regions 300A and 300B, and completely covers the well regions 300A and 300B. In addition, the second conductive structure 600 also spans over the first doping region 410A and the first doping region 410B, but does not completely cover the first doping region 410A and the first doping region 410B. That is, a portion of the top surface of the first doping region 410A and the first doping region 410B is covered by the second conductive structure 600, while the other portion is exposed. In the embodiment of FIG. 1, in the first direction X, the second conductive structure 600 is disposed between the first conductive structure 500A and the first conductive structure 500B.

The second electrode structure 600 may be a general planar gate structure (as shown in FIG. 1) or a split gate planar gate structure (as shown in FIG. 5). In the embodiment of FIG. 1, the second conductive structure 600 is a general gate planar structure, which includes a second conductive layer 610 and a second dielectric layer 620 surrounding the second conductive layer 610. In the embodiment of FIG. 1, the second conductive layer 610 itself may also be regarded as the gate of the semiconductor device 10.

In some embodiments, the materials and methods of the second conductive layer 610 and the second dielectric layer 620 may be similar to the materials of the first conductive layer 510A or 510B and the first dielectric layer 520A or 520B, and thus they will not be repeated in detail here.

For example, the formation of the second conductive structure 600 may include the following steps: forming a gate oxide layer at a predetermined position through an oxidation process; depositing a conductive material on the gate oxide layer through a deposition process; then removing an excess conductive material through a removal process to form a second conductive layer 610; and forming a top dielectric layer on the second conductive layer through a deposition process. The shielding dielectric layer and the top dielectric layer may be regarded as the second dielectric layer 620.

In some embodiments, the semiconductor device 10 further includes an upper electrode layer 700 and a lower electrode layer 800, which are respectively disposed on the epitaxial layer 200 and under the substrate 100. That is, the upper electrode layer 700 and the lower electrode layer 800 are located on both sides of the substrate 100 respectively. More specifically, the upper electrode layer 700 and the lower electrode layer 800 are respectively located on the substrate 100 (the side of +Z direction) and below the substrate 100 (the side of −Z direction). In some embodiments, the upper electrode layer 700 and the lower electrode layer 800 are electrically connected to the source and drain (not shown) of the semiconductor device 10 respectively. In the embodiment of FIG. 1, the upper electrode layer 700 and the lower electrode layer 800 themselves may also be regarded as the source and drain of the semiconductor device 10 respectively.

In some embodiments, the upper electrode layer 700 and the lower electrode layer 800 may include the same or different materials, which may be metal or metal nitride. For example, platinum (Pt), titanium (Ti), titanium nitride (TiN), tantalum (Ta), tantalum nitride (TaN), tungsten (W), tungsten nitride (WN), gold (Au), iron (Fe), nickel (Ni), beryllium (Be), chromium (Cr), cobalt (Co), antimony (Sb), iridium (Ir), molybdenum (Mo), osmium (Os), thorium (Th), vanadium (V) or a combination of the foregoing.

In some embodiments, the upper electrode layer 700 and the lower electrode layer 800 may be formed by a deposition process similar to the above, which will not be repeated again. For example, a component process is performed on one side of the substrate 100 (for example, the front side) and the upper electrode layer 700 is formed by a deposition process, sputtering, resistance heating evaporation, electron beam evaporation, or any other suitable metal plating process. The lower electrode layer 800 is then provided on the other side (for example, the back side) of the substrate 100 by the similar method.

Based on the above, the embodiment of the present disclosure is achieved by combining the first conductive structure 500 (including the first conductive structure 500A and the first conductive structure 500B) and the second conductive structure 600 (that is, combining the trench gate structure and the planar gate structure). It may increase the electron current flow path and improve the electron current density.

Specifically, as shown in FIG. 1, a current eA1 and a current eB1 are generated under both sides of the second conductive structure 600A. Furthermore, a current eA2 and a current eB2 are generated on one side of the first conductive structure 500A (for example, the side of the +X direction) and on one side of the first conductive structure 500B (for example, the side of the −X direction). That is, the well region 300A has a channel region CA1 close to the second conductive structure 600 and a channel region CA2 close to the first conductive structure 500A, and the well region 300B has a channel region CB1 close to the second conductive structure 600 and a channel region CB2 close to the first conductive structure 500B.

In other words, compared to using the trench gate structure or the planar gate structure alone, embodiments of the present disclosure may generate twice the current path and twice the current density by combining them.

Next, please referring to FIG. 1-1 and FIG. 1-2, in the embodiment of FIG. 1-1, the well region 300A and the well region 300B are located on both sides of the epitaxial layer 200. The doping region 400 (including the first doping region 410 and the second doping region 420) is located on both sides of the well regions 300A and 300B. Specifically, the first doping region 410A and the first doping region 410B are respectively located on the left side (the side of −X direction) of the well region 300A and on the right side (the side of +X direction) of the well region 300B. The plurality of second doping regions 420A and the plurality of second doping regions 420B are respectively located in the first doping region 410A and the first doping region 410B. More specifically, the plurality of second doping regions 420A are separated from each other by the first doping regions 410A, and the plurality of second doping regions 420B are separated from each other by the first doping regions 410B.

The difference between FIG. 1-2 and FIG. 1 is that the semiconductor device 10 further includes a second doping region 420 (including a second doping region 420A and a second doping region 420B). In the embodiment of FIG. 1-2, the second doping region 420A and the second doping region 420B are located under both sides of the second conductive structure 600. In addition, the first doping region 410A is disposed on both sides of the second doping region 420A, and the first doping region 410B is disposed on both sides of the second doping region 420B. In detail, in the first direction X, the second doping region 420A is spaced apart from the well region 300A by the first doping region 410A, and is also spaced apart from the first conductive structure 500A by the first doping region 410A. Similarly, in the first direction X, the second doping region 420B is spaced apart from the well region 300B by the first doping region 410B, and is also spaced apart from the first conductive structure 500B by the first doping region 410B. In this way, the well regions 300A and 300B may be connected to the source through good ohmic contact to reduce the influence of the body effect and stabilize the starting voltage.

In some embodiments, the second doping region 420 has a second conductivity type, such as p-type. In some embodiments, the doping concentration of the second doping region 420 may be approximately 10¹⁹-10²¹ atoms/cm³ to facilitate the subsequent formation of an ohmic contact interface with the metal thereon.

### Second Embodiment

According to a second embodiment of some embodiments of the present disclosure, FIG. 2 shows a cross-sectional view of the semiconductor device 20 along the section line AA′. The semiconductor device 20 is similar to the semiconductor device 10, and the difference is that the semiconductor device 20 further includes a shielding layer 900 disposed under the first conductive structure 500. That is, the structural unit U2 of the semiconductor device 20 further includes a pair of shielding layers 900A and 900B. Specifically, the shielding layer 900A and the shielding layer 900B are respectively disposed under the first conductive structure 500A and the first conductive structure 500B. For example, the shielding layer 900A covers the bottom surface of the first conductive structure 500A. Thereby, the electric field under the first conductive structure 500 may be further reduced and the parasitic capacitance between the gate and the drain may be reduced.

In some embodiments, the shielding layer 900 may be electrically connected to the source (for example, may have a ground potential). In some embodiments, the shielding layer 900 has a second conductivity type, such as p-type. In some embodiments, the doping concentration of the shielding layer 900 may be approximately 5×1016-5×10¹⁷ atoms/cm³. In some embodiments, shielding layer 900 has the ground potential. In some embodiments, the structural unit U2 has a pitch P2 that is substantially the same as the pitch P1 of the structural unit U1.

### Third Embodiment

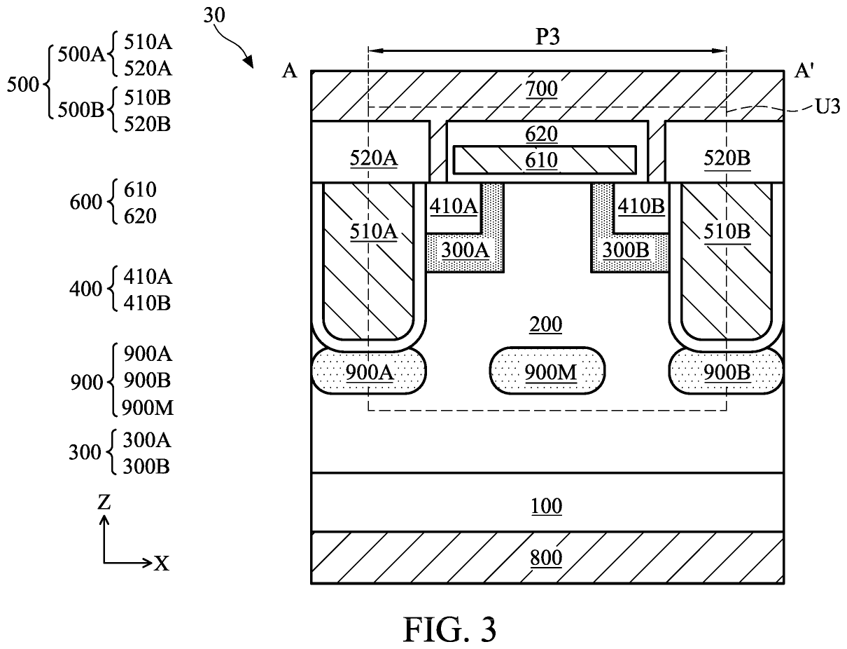

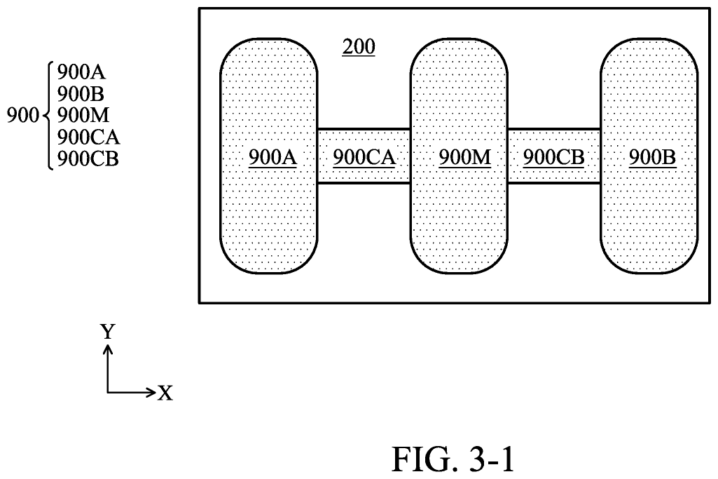

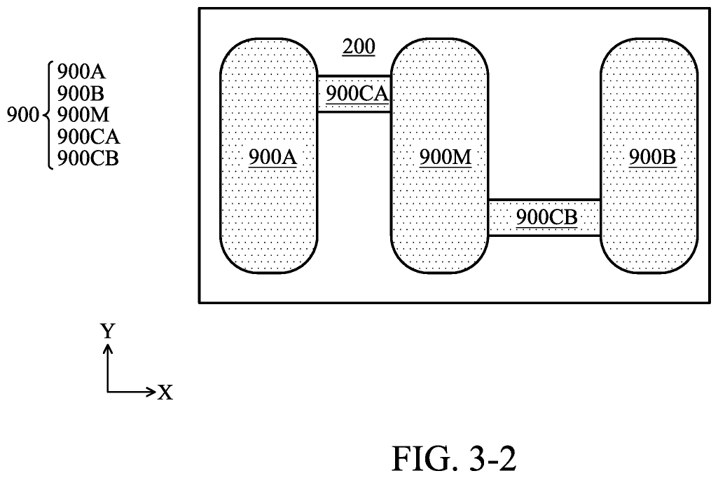

According to a third embodiment of some embodiments of the present disclosure, FIG. 3 shows a cross-sectional view of the semiconductor device 30 along the section line AA′. The semiconductor device 30 is similar to the semiconductor device 20, and the difference is that the semiconductor device 30 further includes a shielding layer 900M disposed in the epitaxial layer 200 and between the shielding layer 900A and the shielding layer 900B. That is, the structural unit U3 of the semiconductor device 30 further includes the shielding layer 900M. In some embodiments, the shielding layer 900M may be connected to or separated from shielding layers 900A and 900B, and may also have the ground potential. In the embodiment of FIG. 3, in the first direction X, the shielding layer 900M is separated from the shielding layer 900A and the shielding layer 900B by the epitaxial layer 200. In some embodiments, the shielding layer 900M may be located anywhere between shielding layer 900A and shielding layer 900B. In the embodiment of FIG. 3, the shielding layer 900M is located right in the middle of the shielding layer 900A and the shielding layer 900B. In some embodiments, in the height direction Z, the shielding layer 900M is separated from the second conductive structure 600 by the epitaxial layer 200. Thereby, the breakdown voltage of the semiconductor device is increased.

In some embodiments, the conductivity type and doping concentration of the shielding layer 900M are similar to those of the shielding layer 900A and the shielding layer 900B, and thus will not be described again. In some embodiments, the structural unit U3 has a pitch P3 that is substantially the same as the pitch P2 of the structural unit U2.

FIG. 3-1 and FIG. 3-2 respectively show top views of different examples of connecting the shielding layer 900A, the shielding layer 900B and the shielding layer 900M. In the embodiments of FIGS. 3-1 and 3-2, the semiconductor device 30 further includes a shielding layer 900CA and a shielding layer 900CB, respectively connecting the shielding layer 900A and the shielding layer 900M, and the shielding layer 900B and the shielding layer 900M. That is, the structural unit U3 of the semiconductor device 30 further includes at least two shielding layers (e.g., the shielding layer 900CA and the shielding layer 900CB) as connecting bridges between the shielding layer 900A, the shielding layer 900B, and the shielding layer 900C. Thereby, the shielding layers 900 may have the same electrical properties as each other, such as ground potential.

In the embodiment of FIG. 3-1, the shielding layer 900M is symmetrical to the central line. That is, the shielding layer 900CA and the shielding layer 900CB are located on both sides of the shielding layer 900M and overlap in the second direction Y. Furthermore, the length of the shielding layer 900CA is the same as the length of the shielding layer 900CB. That is, the distance between the shielding layer 900A and the shielding layer 900M is the same as the distance between the shielding layer 900B and the shielding layer 900M. Thereby, the current is more stable and the breakdown voltage is also more stable.

In the embodiment of FIG. 3-2, the shielding layer 900M is not symmetrical to the central line. That is, although the shielding layer 900CA and the shielding layer 900CB are located on both sides of the shielding layer 900M, they do not overlap in the second direction Y. Specifically, the shielding layer 900CA is located on the side of +Y direction, and the shielding layer 900CB is located on the side of −Y direction. Furthermore, the length of the shielding layer 900CA is different from the length of the shielding layer 900CB. That is, the distance between the shielding layer 900A and the shielding layer 900M is different from the distance between the shielding layer 900B and the shielding layer 900M. In the embodiment of FIG. 3-2, the length of the shielding layer 900CA is shorter than the length of the shielding layer 900CB.

### Fourth Embodiment

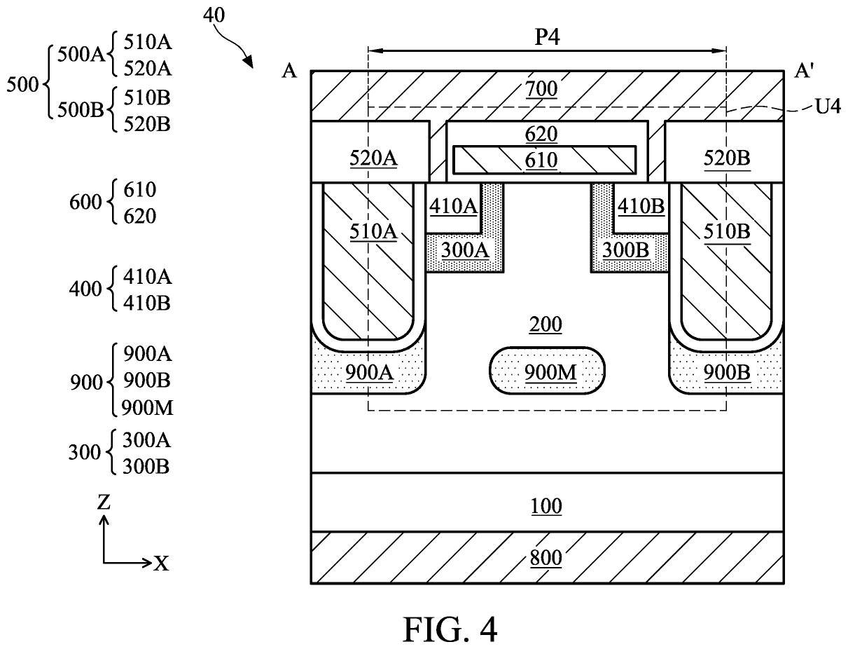

According to a fourth embodiment of some embodiments of the present disclosure, FIG. 4 shows a cross-sectional view of the semiconductor device 40 along the section line AA′. The semiconductor device 40 is similar to the semiconductor device 40, and the difference is that the shielding layer 900A and the shielding layer 900B of the semiconductor device 40 cover the bottom corners of the first conductive structures 500A and 500B. That is, the shielding layer 900A completely covers the bottom surface of the first conductive structure 500A, and the shielding layer 900B completely covers the bottom surface of the first conductive structure 500B. Thereby, the surface electric field at the corners of the first conductive structure 500 may be further reduced, and problems such as thermal runaway may also be reduced.

In some embodiments, the shielding layer 900A and the shielding layer 900B may cover a portion of the sidewalls of the first conductive structure 500A and a portion of the sidewalls of the first conductive structure 500B. In some embodiments, the structural unit U4 has a pitch P4 that is substantially the same as the pitch P3 of the structural unit U3.

### Fifth Embodiment

According to a fifth embodiment of some embodiments of the present disclosure, FIG. 5 shows a cross-sectional view of the semiconductor device 50 along the section line AA′. The semiconductor device 50 is similar to the semiconductor device 30, and the difference is that the first conductive structure 500 of the semiconductor device 50 is a split trench gate structure and the second conductive structure 600 is a split planar gate structure. Specifically, the first conductive structure 500A further includes a bottom conductive layer 530A, which is separated from the first conductive layer 510A by a first dielectric layer 520A. The first conductive structure 500B further includes a bottom conductive layer 530B separated from the first conductive layer 510B by a first dielectric layer 520B. The second conductive layer 610 of the second conductive structure 600 includes a pair of second conductive layers 610A and 610B surrounded by the second dielectric layer 620.

In some embodiments, the bottom conductive layer (such as bottom conductive layer 530A or 530B) and the first conductive layer (such as first conductive layer 510A or 510B) may be electrically connected to the source and the gate respectively to shield the capacitance charge and discharge paths in the gate and drift regions (such as epitaxial layer 200). Thus, the gate-to-drain capacitance (Cgd) may be further reduced, and the switching characteristics of the semiconductor device may be improved. In some embodiments, the bottom conductive layer (such as bottom conductive layer 530A) is in direct contact with the shielding layer (such as shielding layer 900A).

In some embodiments, the bottom conductive layer 530A or 530B may include materials similar to the first conductive layer 510A or 510B, and thus will not be described again. In some embodiments, the bottom conductive layer 530A or 530B may selectively include a second conductivity type dopant such as p-type, which may be aluminum (Al), boron (B), boron difluoride (BF₂), or another suitable admixture.

In some embodiments, the second conductive layer 610A and the second conductive layer 610B are separated by the second dielectric layer 620, which may reduce the area of the gate electrode covering the current dispersion layer and may further reduce the gate-to-drain capacitance (Cgd). In some embodiments, both the second conductive layer 610A and the second conductive layer 610B are electrically connected to the gate.

In some embodiments, the second conductive layer 610A and the second conductive layer 610B may include materials similar to the second conductive layer 610, which will not be described again.

In some embodiments, the structural unit U5 has a pitch P5, which is substantially the same as the pitch P3 of the structural unit U3.

### Sixth Embodiment

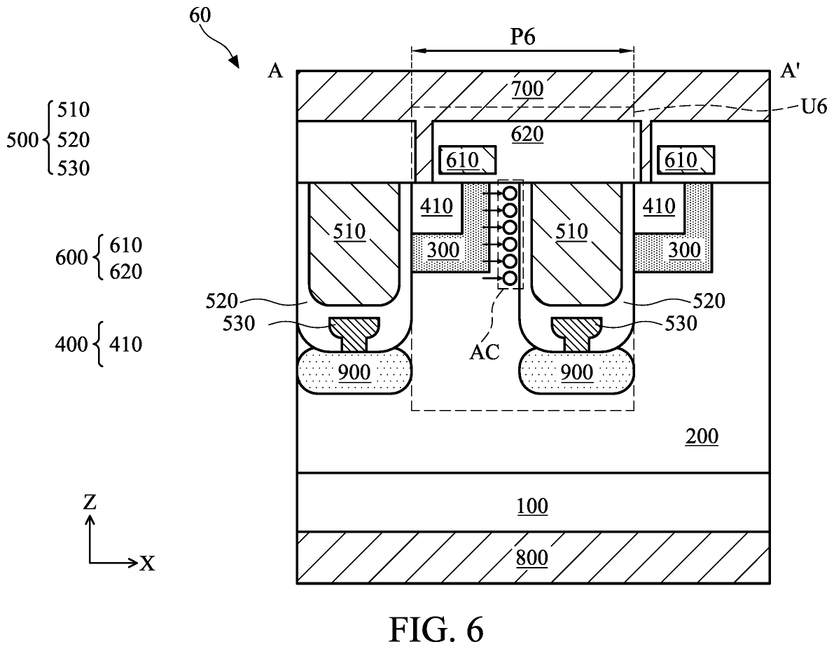

According to a sixth embodiment of some embodiments of the present disclosure, FIG. 6 shows a cross-sectional view of the semiconductor device 60 along the section line AA′. The semiconductor device 60 is similar to the semiconductor device 50, and the difference is that the relative positions of the well regions 300 and the first conductive structures 500 of the semiconductor device 60, and the semiconductor device 60 further includes another second conductive structure 600. Specifically, the well region 300 (corresponding to the well region 300A in FIG. 5) is disposed between the first conductive structure 500 (corresponding to the first conductive structure 500A in FIG. 5) and another first conductive structure 500 (corresponding to the first conductive structure 500B in FIG. 5). Another well region 300 (corresponding to the well region 300B in FIG. 5) is disposed beyond the first conductive structure 500 and the other first conductive structure 500. Specifically, the well region 300 is separated from another first conductive structure 500 by the epitaxial layer 200.

Furthermore, the second conductive structure 600 and the other second conductive structure 600 are general planar gate structures. Specifically, the second conductive structure 600 includes a second conductive layer 610 and a second dielectric layer 620 surrounding the second conductive layer 610, and the other second conductive structure 600 also includes another second conductor layer 610 and another second dielectric layer 620 surrounding the other second conductor layer 610.

In some embodiments, the second conductive layer 610 and the other conductive layer 610 are respectively disposed on the well region 300 and the other well region 300. For example, one side of the second conductive layer 610 is located on the first doping region 410 and the other side is located on the epitaxial layer 200. That is, the second conductive layer 610 spans over the well region 300 from the first doping region 410 to the epitaxial layer 200.

In some embodiments, the second conductive structure 600 is in contact with the first conductive structure 500, and the other second conductive structure 600 is in contact with the other first conductive structure 500. For example, the first conductive layer 510 and the first dielectric layer 520 are in direct contact with the second dielectric layer 620.

In the embodiment of FIG. 6, the structural unit U6 is not symmetrical to the central line of the second conductive structure 600. Specifically, the structural unit U6 includes: a well region 300 disposed in the epitaxial layer 200, a first doping region 410 disposed in the well region 300, a first conductive structure 500 disposed in the epitaxial layer 200 and a second conductive structure 600 disposed on the epitaxial layer 200. Furthermore, the well region 300 and the first conductive structure 500 are respectively disposed under both sides of the second conductive structure 600. In some embodiments, the structural unit U6 further includes a shielding layer 900 disposed under the first conductive structure 500. Its materials and functions are similar to those described above and will not be described again. In some embodiments, the structural unit U6 further includes an electron accumulation layer AC disposed on one side of the first conductive structure 500. In detail, the electron accumulation layer AC may cover the entire side surface of the first conductive structure 500. Thereby, the current density may be further increased and the on-resistance may be reduced, thereby improving the conductive characteristics of the semiconductor device.

In some embodiments, the structural unit U6 has a pitch P6 that is approximately half of the pitch P5 of the structural unit U5. That is, two structural units U6 may be equivalent to one structural unit U5. This will further improve semiconductor performance.

In summary, embodiments of the present disclosure reduce the on-voltage while maintaining the breakdown voltage by combining the first conductive structure and the second conductive structure. Furthermore, in the embodiment of the present disclosure, the first conductive structure and the second conductive structure share a well region, which may reduce process complexity.

In addition, in embodiments of the present disclosure, by providing a shielding layer at the bottom of the first conductive structure, the electric field of the conductive structure may be further reduced. In addition, embodiments of the present disclosure may increase the breakdown voltage by further disposing a shielding layer between a pair of first conductive structures. In addition, in embodiments of the present disclosure, the shielding layer covers the bottom edge of the first conductive structure, which may further reduce the electric field at the corners of the conductive structure. In addition, by disposing split gate conductive structures, embodiments of the present disclosure may further reduce the electric field at the corners of the conductive structures. In addition, the embodiments of the present disclosure use asymmetric structural units to not only reduce the distance between the structural units, but also form an electron accumulation layer on one side of the conductive structure to further reduce the on-resistance.

The protection scope of the present disclosure is not limited to the process, machine, manufacture, material composition, device, method and step in the specific embodiments described in the specification. In the disclosure of the embodiments, it is understood that current or future processes, machines, manufactures, compositions of matter, devices, methods and steps can be implemented as long as substantially the same functions or substantially the same results can be achieved in the embodiments described herein. Use according to some embodiments of the present disclosure. Therefore, the protection scope of the present disclosure includes the aforementioned process, machine, manufacture, composition of matter, apparatus, method and steps. In addition, each claimed scope constitutes a separate embodiment, and the protection scope of the present disclosure also includes the combination of each claimed scope and the embodiments.

While the embodiments and the advantages of the present disclosure have been described above, it should be understood that those skilled in the art may make various changes, substitutions, and alterations to the present disclosure without departing from the spirit and scope of the present disclosure. It should be noted that different embodiments may be arbitrarily combined as other embodiments as long as the combination conforms to the spirit of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. A semiconductor device, comprising:
a substrate;
an epitaxial layer disposed on the substrate, wherein the epitaxial layer has a first conductivity type;
a pair of well regions disposed in the epitaxial layer, wherein the pair of well regions has a second conductivity type that is different from the first conductivity type;
a pair of doping regions disposed in the pair of well regions, wherein the pair of doping regions has the first conductivity type;
a pair of first conductive structures disposed on sides of the pair of well regions, respectively; and
a second conductive structure disposed on the pair of well regions.

2. The semiconductor device as claimed in claim 1, further comprising a pair of shielding layers disposed under the pair of first conductive structures, respectively, wherein the pair of shielding layers has the second conductivity type.

3. The semiconductor device as claimed in claim 1, further comprising a shielding layer disposed in the epitaxial layer, wherein the shielding layer is spaced apart from the second conductive structure by the epitaxial layer, wherein the shielding layer has the second conductivity type.

4. The semiconductor device as claimed in claim 1, wherein the second conductive structure comprises a second conductive layer and a second dielectric layer surrounding the second conductive layer.

5. The semiconductor device as claimed in claim 1, wherein the second conductive structure comprises a pair of second conductive layers and a second dielectric layer surrounding the pair of second conductive layers.

6. The semiconductor device as claimed in claim 1, wherein each of the first conductive structures comprises a first conductive layer and a dielectric layer surrounding the first conductive layer.

7. The semiconductor device as claimed in claim 6, wherein the pair of first conductive structures further comprises a pair of bottom conductive layers, wherein the pair of bottom conductive layers are spaced apart from the pair of first conductive layers by the pair of first dielectric layers.

8. The semiconductor device as claimed in claim 1, wherein the pair of well regions is disposed between the pair of first conductive structures.

9. The semiconductor device as claimed in claim 1, wherein one of the well regions is disposed between the pair of first conductive structures, and the other well region is disposed beyond the pair of first conductive structures.

10. The semiconductor device as claimed in claim 9, further comprising another second conductive structure, wherein the second conductive structure and the another second conductive structure comprise: a pair of conductive layers disposed on the pair of well regions and a pair of second dielectric layers respectively surrounding the pair of second conductive layers.

11. The semiconductor device as claimed in claim 10, wherein the second conductive structure is in contact with one of the first conductive structures, and the other second conductive structure is in contact with the other first conductive structure.

12. The semiconductor device as claimed in claim 1, further comprising an upper electrode layer and a lower electrode layer respectively disposed on the epitaxial layer and under the substrate.

13. A semiconductor device, comprising:
A substrate;
an epitaxial layer disposed on the substrate, wherein the epitaxial layer has a first conductivity type;
at least one structural unit, wherein each of the structural units comprises:
a pair of first conductive structures disposed on an outermost side of the structural unit;
a second conductive structure disposed on the epitaxial layer;
a pair of well regions disposed between the pair of first conductive structures, wherein the pair of well regions has a second conductivity type that is different from the first conductivity type; and
a pair of doping regions disposed in the pair of well regions, wherein the pair of doping regions has the first conductivity type,
wherein each of the structural units is symmetrical to a center of the second conductive structure.

14. The semiconductor device as claimed in claim 13, wherein the structural unit further comprises at least two shielding layers, wherein in a top view, the shielding layers are connected to each other.

15. A semiconductor device, comprising:
a substrate;
an epitaxial layer disposed on the substrate, wherein the epitaxial layer has a first conductivity type;
at least one structural unit, wherein each of the structural units comprises:
a well region disposed in the epitaxial layer, wherein the well region has a second conductivity type that is different from the first conductivity type;
a doping region disposed in the well region, wherein the doping region has the first conductivity type;
a first conductive structure disposed in the epitaxial layer; and
a second conductive structure disposed on the epitaxial layer,
wherein the well region and the first conductive structure are respectively disposed under opposing sides of the second conductive structure.

16. The semiconductor device as claimed in claim 15, wherein the first conductive structure comprises a first conductive layer and a dielectric layer surrounding the first conductive layer, wherein the second conductive structure comprises a second conductive layer and a second dielectric layer surrounding the second conductive layer, wherein the first conductive layer and the first dielectric layer are in direct contact with the second dielectric layer.

17. The semiconductor device as claimed in claim 16, wherein the second conductive layer is disposed directly above the well region.

18. The semiconductor device as claimed in claim 15, wherein the first conductive structure is spaced apart from the well region by the epitaxial layer.

19. The semiconductor device as claimed in claim 15, wherein each of the structural units further comprises a shielding layer disposed under the first conductive layer, wherein the shielding layer has the second conductivity type.

20. The semiconductor device as claimed in claim 15, wherein each of the structural units further comprises an electron accumulation layer disposed on a side of the first conductive structure.
